(19) United States
(12) Patent Application Publication
(10) Pub. No.: US 2020/0126995 A1
(43) Pub. Date: Apr. 23, 2020

(54) MEMORY IMPLEMENTED USING NEGATIVE CAPACITANCE MATERIAL

(71) Applicant: QUALCOMM Incorporated, San Diego, CA (US)

(72) Inventors: Lixin GE, San Diego, CA (US); Ye LU, San Diego, CA (US); Bin YANG, San Diego, CA (US)

(21) Appl. No.: 16/165,028

(22) Filed: Oct. 19, 2018

(51) Int. Cl. H01L 27/108

(52) U.S. Cl. CPC H01L 27/10829; H01L 29/94; H01L 27/1087; H01L 27/10873

(57) ABSTRACT

Certain aspects of the present disclosure provide a memory implemented using negative capacitance material. One example memory generally includes a transistor coupled to a word-line of the memory and a bit-line of the memory, and a capacitive element coupled to the transistor. The capacitive element may include a first layer of dielectric material and a second layer of negative capacitance material, the first layer and the second layer being between a first non-insulative region coupled to the transistor and a second non-insulative region.

### TECHNICAL FIELD

The teachings of the present disclosure relate generally to memory, and more particularly, to an implementation of memory using negative capacitance material.

### INTRODUCTION

A dynamic random-access memory (DRAM) is a type of random-access memory that stores each bit of data in a capacitor. Due to leakage current, the charge stored in the capacitor leaks, and thus, the capacitor may be recharged at a periodic rate. Without recharging the capacitor, the stored data would eventually be lost. The charge of the capacitor may be refreshed by periodically reading information (e.g., the bit stored in the capacitors) from an area of memory and rewriting the information to the same area without modification, for the purpose of preserving the information.

### BRIEF SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure provide a memory implemented using negative capacitance material.

In certain aspects, the memory generally includes a transistor coupled to a word-line of the memory and a bit-line of the memory, and a capacitive element coupled to the transistor. The capacitive element may include a first layer of dielectric material and a second layer of negative capacitance material, the first layer and the second layer being between a first non-insulative region coupled to the transistor and a second non-insulative region.

In certain aspects, the memory includes a plurality of word-lines, a plurality of bit-lines, and a plurality of memory cells. Each of the plurality of memory cells may include a transistor coupled to a word-line of the plurality of word-lines and a bit-line of the plurality of bit-lines, and a capacitive element coupled to the transistor. In certain aspects, the capacitive element includes a first layer of dielectric material and a second layer of negative capacitance material, the first layer and the second layer being between a first non-insulative region coupled to the transistor and a second non-insulative region.

Certain aspects of the present disclosure provide a method for fabricating a memory. The method generally includes forming a transistor coupled to a word-line of the memory and a bit-line of the memory, and forming a capacitive element coupled to the transistor. In certain aspects, forming the capacitive element includes forming a first layer of dielectric material, and forming a second layer of negative capacitance material, the first layer and the second layer being formed between a first non-insulative region coupled to the transistor and a second non-insulative region.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is an illustration of an exemplary system-on-chip (SoC) integrated circuit design, in accordance with certain aspects of the present disclosure.

FIG. 2A illustrates an example memory having multiple memory cells coupled to bit-lines and word-lines of the memory, in accordance with certain aspects of the present disclosure.

FIG. 2B illustrates an example memory cell of the memory of FIG. 2A, in accordance with certain aspects of the present disclosure.

FIG. 3A illustrates an example memory cell of a memory implemented with a trench, in accordance with certain aspects of the present disclosure.

FIG. 3B illustrates a capacitive element implemented using traditional capacitive material connected in series with a capacitive element implemented using negative capacitance material, in accordance with certain aspects of the present disclosure.

FIGS. 4A and 4B illustrate example memory cells of a DRAM, in accordance with certain aspects of the present disclosure.

FIG. 5 is a flow diagram of example operations for fabricating a memory, in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

The various aspects will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., ROM, RAM, flash, etc.), and resources (e.g., timers, voltage regulators, oscillators, etc.), any or all of which may be included in one or more cores.

A number of different types of memories and memory technologies are available or contemplated in the future, all of which are suitable for use with the various aspects of the present disclosure. Such memory technologies/types include dynamic random-access memory (DRAM), static random-access memory (SRAM), non-volatile random-access memory (NVRAM), flash memory (e.g., embedded multimedia card (eMMC) flash), pseudostatic random-access memory (PSRAM), double data rate synchronous dynamic random-access memory (DDR SDRAM), and other random-access memory (RAM) and read-only memory (ROM) technologies known in the art. A DDR SDRAM memory may be a DDR type 1 SDRAM memory, DDR type 2 SDRAM memory, DDR type 3 SDRAM memory, or a DDR type 4 SDRAM memory. Each of the above-mentioned memory technologies includes, for example, elements suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

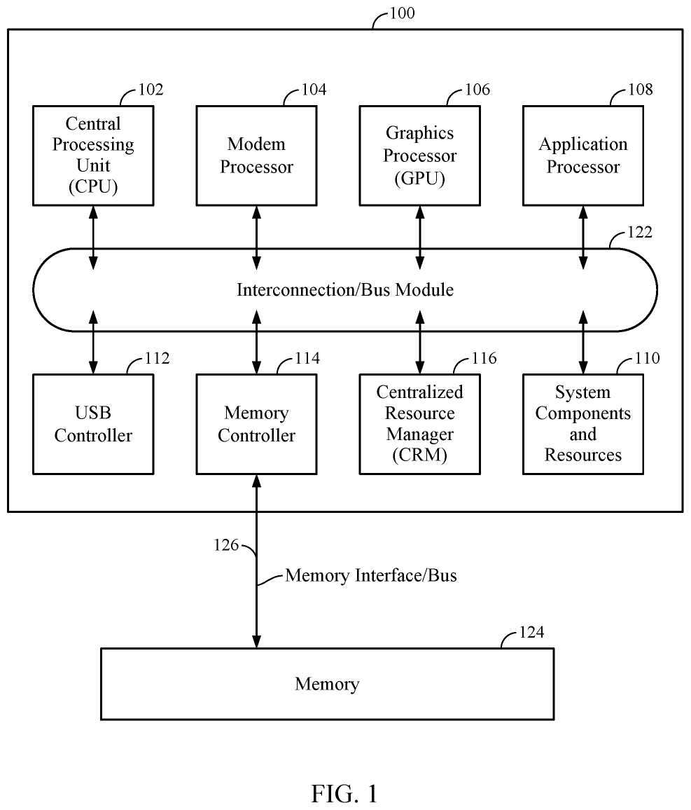

FIG. 1 illustrates example components and interconnections in a system-on-chip (SoC) 100 suitable for implementing various aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture (e.g., CoreConnect, AMBA, etc.). Communications may also be provided by advanced interconnects, such as high performance networks on chip (NoCs).

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously.

The memory controller 114 may be a specialized hardware module configured to manage the flow of data to and from a memory 124 (e.g., a DRAM) via a memory interface/bus 126. Certain aspects of the present disclosure are generally directed to a memory implemented using negative capacitance material. For example, the memory 124 may be a DRAM implemented using negative capacitance material, improving the operation efficiency and/or reducing the size of the DRAM, as described in more detail herein.

The memory controller 114 may comprise one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In certain aspects, the memory 124 may be part of the SoC 100.

### Example Memory Implemented Using Negative Capacitance Material

Dynamic random-access memory (DRAM) is a type of random-access memory that stores each bit of data (e.g., in the form of charge) in a separate capacitor using a transistor within an integrated circuit (IC). The DRAM includes multiple memory cells, each including a transistor and a capacitor for storing data. As time passes, the charge in the memory cells dissipates due to leakage current (e.g., due to transistor leakage current), and thus, the memory cells of the DRAM may be recharged at a periodic rate to restore this charge. Without recharging the memory cells, the stored data would eventually be lost. For example, the memory cells of the DRAM may be refreshed by periodically reading information from an area of the DRAM and immediately rewriting the read information to the same area without modification, for the purpose of preserving the information. This memory refresh process involves significant overhead, which reduces the circuit operation efficiency.

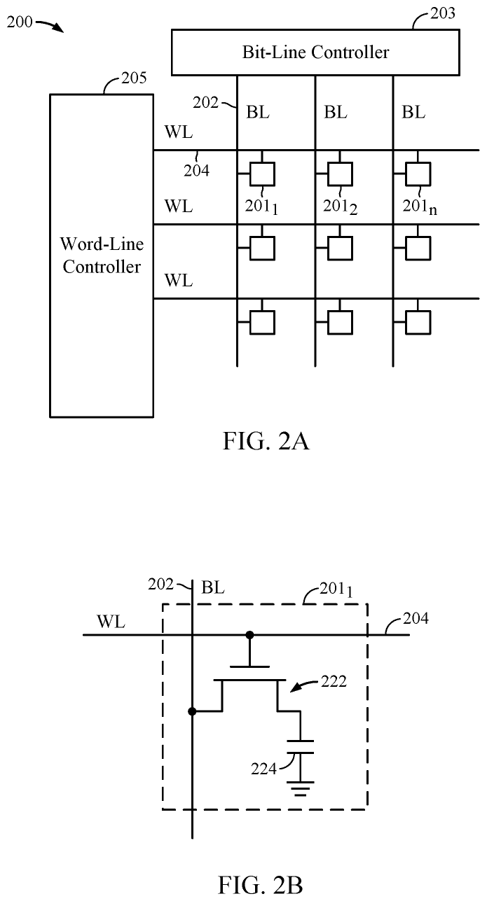

FIG. 2A illustrates an example DRAM 200 having multiple memory cells (e.g., memory cells 201₁, 201₂, to 201ₙ) coupled to the bit-lines (BLs) and word-lines (WLs) of the DRAM, as illustrated. The DRAM 200 also includes a BL controller 203 for controlling the BLs (e.g., BL 202) and a WL controller 205 for controlling the WLs (e.g., WL 204), during read and write operations of the DRAM 200. The BL controller 203 and the WL controller 205 may correspond to the memory controller 114, and the DRAM 200 may correspond to the memory 124, as described with respect to FIG. 1.

FIG. 2B illustrates an example memory cell (e.g., memory cell 201₁) of the DRAM 200. As illustrated, a capacitive element 224 is coupled to a transistor 222 in the memory cell 201₁. As used herein, a “capacitive element” generally refers to an electrical component having a capacitance property, which may be implemented by a capacitor, a transistor, or any of various other suitable components. The gate of transistor 222 may be coupled to the WL 204 of the DRAM 200, and a drain of the transistor 222 may be coupled to the BL 202 of the DRAM 200. The BL may be charged, and the WL may be used to bias the gate of the transistor 222, to transfer the charge from the BL to the capacitive element 224, during a write operation. The capacitive element 224 stores the charge for a certain period of time, depending on the amount of leakage current that may be draining the charge from the capacitive element 224, as previously described.

Certain aspects of the present disclosure are generally directed to increasing the capacitance of the capacitive elements (e.g., capacitive element 224) of the DRAM 200, by implementing the capacitive elements using negative capacitance material. For example, implementing the capacitive elements of the DRAM using negative capacitance material may increase the capacitance of the capacitive elements by a factor of ten. Increasing the capacitance of the DRAM allows for an increase in the refresh interval and the efficiency of the DRAM, and/or allows for reducing the DRAM device size due to the effective capacitance density of the DRAM being increased, as will be described in more detail herein. In certain aspects, the negative capacitance material may include lead zirconium titanium oxide, (Pb(Zr_{0.2}Ti_{0.8})O₃), hafnium zirconium oxide (Hf_{0.42}Zr_{0.58}O₂), or aluminum indium nitride (Al_{0.83}In_{0.17}N), for example.

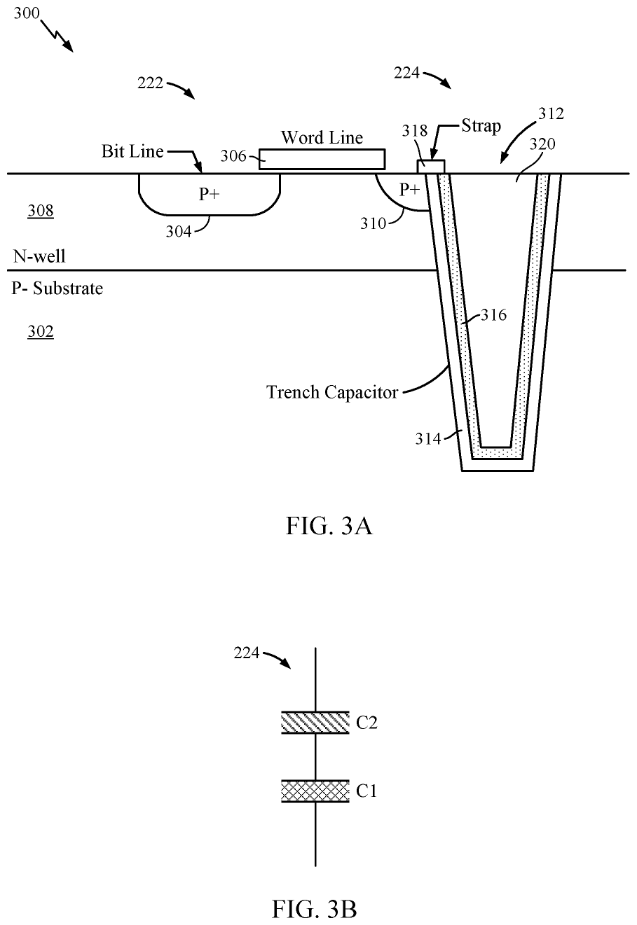

FIG. 3A illustrates an example memory cell 300 of a DRAM, in accordance with certain aspects of the present disclosure. The memory cell 300 may correspond to any of the memory cells described with respect to FIGS. 2A and 2B, such as the memory cell 201₁. As illustrated, the memory cell 300 includes a transistor 222 formed using a semiconductor region 308 (e.g., an N-well region), a non-insulative region 304 (e.g., a P+ doped semiconductor region), a non-insulative region 310 (e.g., a P+ doped semiconductor region), and a gate region (e.g., non-insulative region 306), as illustrated. In certain aspects, the semiconductor region 308 may be located above a substrate 302 (e.g., P-type substrate). In certain aspects, the non-insulative region 304 may be coupled to the BL of the DRAM, and the non-insulative region 306 may be coupled to the WL of the DRAM. As used herein, a “non-insulative region” generally refers to a region that may be electrically conductive or semiconductive.

The non-insulative region 310 may be coupled to a capacitive element 224 to store a charge, as described with respect to FIG. 2B. For example, a trench 312 may be adjacent to the non-insulative region 310. A layer of dielectric material 314 and a layer of negative capacitance material 316 may be formed in the trench 312, as illustrated. The trench 312 is also filled with non-insulative material to form a non-insulative region 320, which may be coupled to a reference potential node (e.g., electric ground) of the DRAM. While the example memory cell 300 illustrates the layer of negative capacitance material 316 being between the layer of dielectric material 314 and the non-insulative region 320 to facilitate understanding, the positions of the layer of dielectric material 314 and the layer of negative capacitance material 316 may be switched in some aspects. In certain aspects, this so-called trench capacitor may include multiple layers of dielectric material and/or multiple layers of negative capacitance material. For example, another layer of negative capacitance material (not shown) may also be included in the trench 312. For example, the layer of dielectric material 314 may be between two layers of negative capacitance material, one on each side of the layer of dielectric material 314, or vice versa. In certain aspects, a strap 318 may be used to couple the non-insulative region 310 to the layer of dielectric material 314.

By implementing the capacitive element 224 for the DRAM using negative capacitance material, the capacitance of the capacitive element may be significantly increased, and thus, the refresh overhead of the DRAM may be decreased. For example, the refresh overhead may be equal to the time involved for refresh to occur divided by the refresh interval. The time involved for refresh to occur is determined by the bus frequency and clock cycles, which may be assumed to be constant in this example to facilitate understanding. The refresh interval is determined based on a ratio of the amount of charge stored in the capacitive element of the memory cell 300 and the amount of leakage current from the capacitive element 224. The leakage current is related to characteristics of the transistor 222, and may be assumed to be constant in this example to facilitate understanding. Thus, increasing the amount of charge that is stored in the capacitive element 224, by increasing the capacitance of the capacitive element 224, provides for an increased refresh interval and, thus, decreases the DRAM refresh overhead. In some cases, instead of (or in conjunction with) decreasing the DRAM refresh overhead, the same DRAM refresh overhead may be maintained, but the size of the DRAM may be reduced due to the effective increase in the capacitance density of the DRAM, as a result of the DRAM capacitive elements being implemented with negative capacitance material.

As illustrated in FIG. 3A, the negative capacitance material 316 may be deposited on top of the dielectric material 314. Therefore, the total dielectric material thickness of the capacitive element 224 is increased, reducing the tunneling or leakage current through the capacitive element 224.

FIG. 3B illustrates a capacitive element C1 implemented using traditional capacitance material (e.g., a dielectric) connected in series with a capacitive element C2 implemented using negative capacitance material, for use in a memory cell (e.g., memory cell 300 of FIG. 3A), for example, in accordance with certain aspects of the present disclosure. Since the capacitance of C2 is negative, the total capacitance (Ctotal) of the capacitive elements C1 and C2 may be equal to:

$$\frac{{c}_{1} \times {c}_{2}}{{c}_{2} - {c}_{1}}$$

where c₁ is absolute value of the capacitance of the capacitive element C1 and c₂ is absolute value of the capacitance of the capacitive element C2. If |c₂| is about 1.1 times |c₁|, then Ctotal may be about 11 times c₁, resulting in an increase in the amount of charge stored in the capacitive element by a factor of 11. Assuming the leakage current remains unchanged, the DRAM refresh interval may be increased by a factor of 11, and the DRAM refresh overhead may be decreased by a factor of 11.

The capacitance (C) of a parallel-plate capacitive element is defined as

$$C = \frac{S}{t} ɛ$$

where ε is the dielectric constant, S is the area of the capacitive element, t is the thickness of the capacitive element between the parallel plates. Therefore, the ratio of the capacitances c₁ and c₂ may be adjusted by adjusting the thickness ratio of the dielectric material 314 and the negative capacitance material 316.

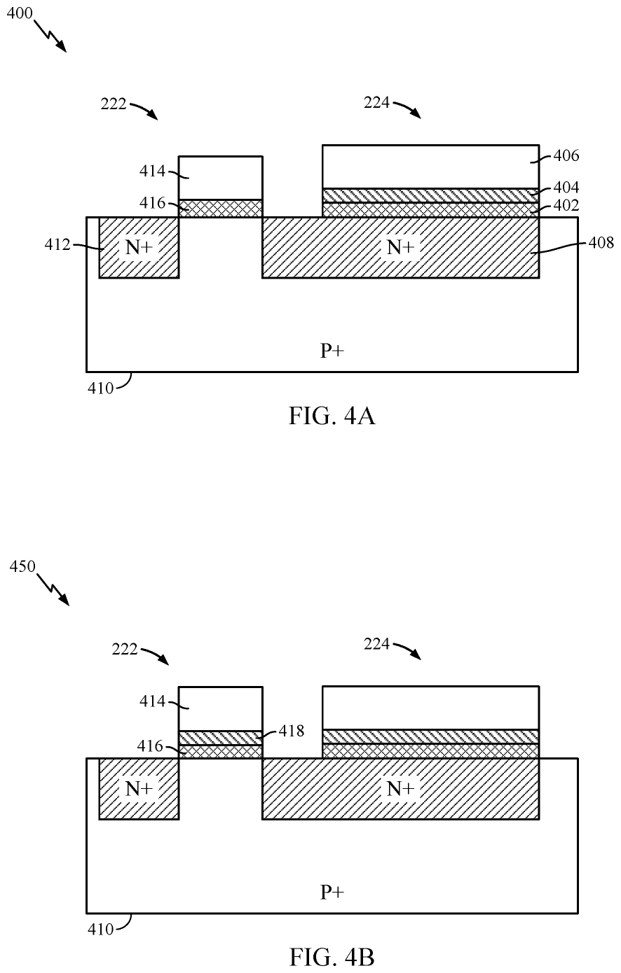

FIGS. 4A and 4B illustrate example memory cells 400 and 450 of a DRAM, respectively, in accordance with certain aspects of the present disclosure. Each of the memory cells 400 and 450 may correspond to any of the memory cells described with respect to FIGS. 2A and 2B, such as the memory cell 201₁. As illustrated, the capacitive element 224 is implemented with a layer of dielectric material 402 and a layer of negative capacitance material 404, both of which are disposed between a non-insulative region 406 and a non-insulative region 408 (e.g., N+ doped semiconductor region). As illustrated, the memory cell 400 includes a transistor 222 formed using a semiconductor region 410 (e.g., a P+ doped semiconductor region), a non-insulative region 412 (e.g., an N+ doped semiconductor region), the non-insulative region 408, and a gate region (e.g., non-insulative region 414), as illustrated. In certain aspects, a layer of dielectric material 416 (e.g., gate oxide) may be disposed between the non-insulative region 414 and the semiconductor region 410.

As illustrated in FIG. 4B, a layer of negative capacitance material 418 may also be disposed between the semiconductor region 410 and the non-insulative region 414 to increase the gate capacitance of the transistor 222. Increasing the gate capacitance of the transistor 222 increases the drive current for charging the capacitive element 224, reducing the charging time of the capacitive element 224 during a write operation.

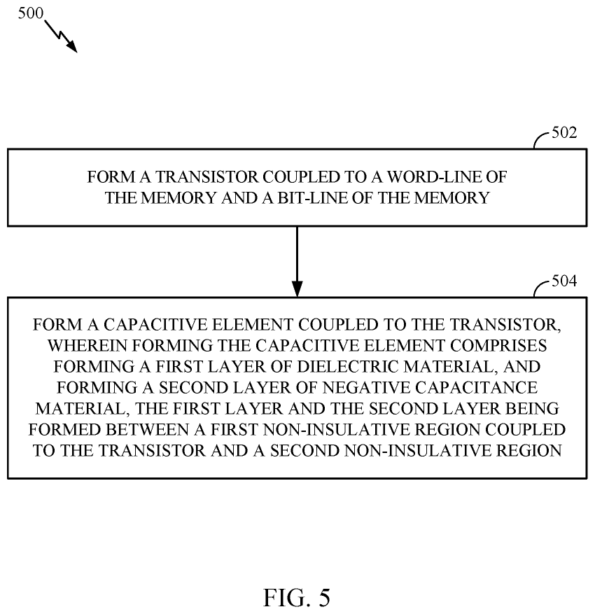

FIG. 5 is a flow diagram of example operations 500 for fabricating a memory, in accordance with certain aspects of the present disclosure. The operations 500 may be performed by a semiconductor processing chamber, for example.

The operations 500 may begin, at block 502, by forming a transistor (e.g., transistor 222) coupled to a word-line (e.g., WL 204) of the memory (e.g., DRAM 200) and a bit-line (e.g., BL 202) of the memory. At block 504, the operations 500 continue by forming a capacitive element (e.g., capacitive element 224) coupled to the transistor. In certain aspects, forming the capacitive element includes forming a first layer of dielectric material (e.g., layer of dielectric material 314 or 416) and forming a second layer of negative capacitance material (e.g., layer of negative capacitance material 316 or 418). In certain aspects, the first layer and the second layer are formed between a first non-insulative region (e.g., non-insulative region 310 or 408) coupled to the transistor and a second non-insulative region (e.g., non-insulative region 320 or 406). In certain aspects of the present disclosure, the second non-insulative region is coupled to a reference potential node (e.g., electric ground) of the memory.

In certain aspects, forming the capacitive element includes forming a trench (e.g., trench 312) adjacent to the transistor. In this case, the first layer, the second layer, and the second non-insulative region are formed in the trench.

In certain aspects, forming the transistor includes forming a first semiconductor region (e.g., semiconductor region 308 or 410), and forming a second semiconductor region (e.g., non-insulative region 304 or 412) adjacent to the first semiconductor region and having a different doping type than the first semiconductor region. The second semiconductor region may be coupled to the bit-line of the memory. Forming the transistor may also include forming a third layer of dielectric material (e.g., layer of dielectric material 416), forming a fourth layer of negative capacitance material (e.g., layer of negative capacitance material 418), and forming a third non-insulative region (e.g., non-insulative region 414) coupled to the word-line of the memory. In certain aspects, the third layer and the fourth layer are formed between the first semiconductor region and the third non-insulative region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein. The algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A memory comprising:
a transistor coupled to a word-line of the memory and a bit-line of the memory; and
a capacitive element coupled to the transistor, wherein the capacitive element comprises a first layer of dielectric material and a second layer of negative capacitance material, the first layer and the second layer being between a first non-insulative region coupled to the transistor and a second non-insulative region.

2. The memory of claim 1, wherein the negative capacitance material comprises lead zirconium titanium oxide, (Pb(Zr_{0.2}Ti_{0.8})O₃), hafnium zirconium oxide (Hf_{0.42}Zr_{0.58}O₂), or aluminum indium nitride (Al_{0.83}In_{0.17}N).

3. The memory of claim 1, wherein the second layer is between the first layer and the second non-insulative region, the second non-insulative region being coupled to a reference potential node of the memory.

4. The memory of claim 1, further comprising a trench disposed adjacent to the transistor, wherein the first layer, the second layer, and the second non-insulative region are disposed in the trench.

5. The memory of claim 4, wherein the second layer is between the first layer and the second non-insulative region in the trench.

6. The memory of claim 1, wherein the transistor comprises:
a first semiconductor region;
a second semiconductor region adjacent to the first semiconductor region and having a different doping type than the first semiconductor region, the second semiconductor region being coupled to the bit-line of the memory;
a third layer of dielectric material; and
a third non-insulative region coupled to the word-line of the memory, wherein the third layer is between the first semiconductor region and the third non-insulative region.

7. The memory of claim 6, wherein the transistor further comprises a fourth layer of negative capacitance material and wherein the fourth layer is between the first semiconductor region and the third non-insulative region.

8. The memory of claim 6, further comprising:
a substrate disposed below the first semiconductor region; and
a trench extending through the first semiconductor region and at least a portion of the substrate, wherein the first layer, the second layer, and the second non-insulative region are disposed in the trench.

9. The memory of claim 1, wherein the memory comprises a dynamic random-access memory (DRAM).

10. A memory comprising:
a plurality of word-lines;
a plurality of bit-lines; and
a plurality of memory cells, wherein each of the plurality of memory cells comprises:
a transistor coupled to a word-line of the plurality of word-lines and a bit-line of the plurality of bit-lines; and
a capacitive element coupled to the transistor, wherein the capacitive element comprises a first layer of dielectric material and a second layer of negative capacitance material, the first layer and the second layer being between a first non-insulative region coupled to the transistor and a second non-insulative region.

11. The memory of claim 10, wherein the first layer is between the second layer and the second non-insulative region, the second non-insulative region being coupled to a reference potential node of the memory.

12. The memory of claim 10, wherein each of the plurality of memory cells comprises a trench disposed adjacent to the transistor and wherein the first layer, the second layer, and the second non-insulative region are disposed in the trench.

13. The memory of claim 12, wherein the second layer is between the first layer and the second non-insulative region in the trench.

14. The memory of claim 10, wherein the transistor comprises:
a first semiconductor region;
a second semiconductor region having a different doping type than the first semiconductor region and being coupled to the bit-line;
a third layer of dielectric material; and
a third non-insulative region coupled to the word-line, wherein the third layer is between the first semiconductor region and the third non-insulative region.

15. The memory of claim 14, wherein the transistor further comprises a fourth layer of negative capacitance material and wherein the fourth layer is between the first semiconductor region and the third non-insulative region.

16. The memory of claim 14, further comprising a substrate disposed below the first semiconductor region, wherein the transistor further comprises a trench extending through the first semiconductor region and at least a portion of the substrate and wherein the first layer, the second layer, and the second non-insulative region are disposed in the trench.

17. The memory of claim 10, wherein the memory comprises a dynamic random-access memory (DRAM).

18. A method for fabricating a memory, comprising:
forming a transistor coupled to a word-line of the memory and a bit-line of the memory; and
forming a capacitive element coupled to the transistor, wherein forming the capacitive element comprises:
forming a first layer of dielectric material; and
forming a second layer of negative capacitance material, the first layer and the second layer being formed between a first non-insulative region coupled to the transistor and a second non-insulative region.

19. The method of claim 18, wherein forming the capacitive element comprises forming a trench adjacent to the transistor and wherein the first layer, the second layer, and the second non-insulative region are formed in the trench.

20. The method of claim 18, wherein forming the transistor comprises:
forming a first semiconductor region;
forming a second semiconductor region adjacent to the first semiconductor region and having a different doping type than the first semiconductor region, the second semiconductor region being coupled to the bit-line of the memory;
forming a third layer of dielectric material;
forming a fourth layer of negative capacitance material; and
forming a third non-insulative region coupled to the word-line of the memory, wherein the third layer and the fourth layer are formed between the first semiconductor region and the third non-insulative region.
